(19) United States
(12) Patent Application Publication
(10) Pub. No.: US 2011/0197438 A1
(43) Pub. Date: Aug. 18, 2011

(54) METHOD OF MANUFACTURING SEMICONDUCTOR DEVICE

(76) Inventors: MASASHI KIKUCHII, Iwate (JP); HIROSHI SATO, Iwate (JP)

(21) Appl. No.: 13/015,680

(22) Filed: Jan. 28, 2011

(30) Foreign Application Priority Data
Feb. 17, 2010 (JP) 2010-032048

(51) Int. Cl. H05K 3/30

(52) U.S. Cl. 29/832

(57) ABSTRACT

A method of manufacturing a semiconductor device includes preparing a flexible printed wiring board having a first connection pad formed on a front surface, a second connection pad formed on a back surface, and a coating film covering regions of the flexible printed wiring board where the first and second connection pads are formed, and a semiconductor package having a third connection pad formed on a hack surface; mounting the semiconductor package on the front surface of the flexible printed wiring board so that the third connection pad is connected to the first connection pad; and folding the flexible printed wiring board so that the second connection pad is located above the front surface of the semiconductor package to face in the same direction as a front surface of the semiconductor package.

This application is based upon and claims the benefit of priority from Japanese patent application No. 2010-32048, filed on Feb. 17, 2010, the disclosure of which is incorporated herein in its entirety by reference.

### BACKGROUND OF THE INVENTION

This invention relates to a method of manufacturing a semiconductor device and in particular to a method of manufacturing a semiconductor device configured by stacking a plurality of semiconductor packages.

A related semiconductor package is configured, for example, by mounting a semiconductor chip on a flexible interposer substrate and then folding the flexible interposer substrate to cover the semiconductor chip (see JP 2004-146751A (Patent Document 1) for example). Such a semiconductor package can be stacked on another semiconductor package having the same configuration to form a single semiconductor device.

In another related semiconductor device, two semiconductor elements are mounted on the same surface of a flexible substrate, and the flexible substrate is folded such that the two semiconductor elements are positioned to face away from each other (see JP 2004-128418A (Patent Document 2), for example).

On the other hand, a method of packaging a semiconductor chip on a substrate is existing, in which an anisotropic conductive film is used (see JP 2003-124258A (Patent Document 3), for example).

A method of packaging a semiconductor device on a substrate is existing, in which each electrode pad of either the semiconductor device or the substrate is formed with a minute projection and each electrode pad of the other one is formed with a minute recess (see JP 2005-26492A (Patent Document 4), for example).

### SUMMARY OF THE INVENTION

There is a demand for a method of manufacturing a semiconductor device having a plurality of stacked semiconductor packages allowing the use of commercially available semiconductor packages.

The semiconductor device described in Patent Document 1 is formed by stacking semiconductor packages having a special configuration. Additionally, in this semiconductor device, the stacked semiconductor packages are mutually connected using solder humps, which increases the thickness in the stacking direction.

Patent Document 2 describes a semiconductor device formed by stacking a plurality of semiconductor elements, while it does not mention at all about stacking commercially available semiconductor packages.

Patent Documents 3 and 4 disclose a method of mounting a semiconductor chip or a semiconductor device on a substrate, while they do not mention at all about stacking commercially available semiconductor packages.

This invention provides a method of manufacturing a semiconductor device formed by stacking a plurality of commercially available semiconductor packages.

A method of manufacturing a semiconductor device according to an aspect of this invention comprises preparing a flexible printed wiring board having a first connection pad formed on a front surface, a second connection pad formed on a back surface, and a coating film covering regions of the flexible printed wiring board where the first and second connection pads are formed, and a semiconductor package having a third connection pad formed on a back surface; mounting the semiconductor package on the front surface of the flexible printed wiring board so that the third connection pad is connected to the first connection pad; and folding the flexible printed wiring board so that the second connection pad is located above the front surface of the semiconductor package to face in the same direction as a front surface of the semiconductor package.

### BRIEF DESCRIPTION OF THE DRAWINGS

FIG. 1A is a schematic diagram showing a configuration of a first semiconductor package used in a method of manufacturing a semiconductor device according to a first embodiment of this invention;

FIG. 1B is a schematic diagram showing the first semiconductor package in which solder balls have been removed;

FIG. 1C is a schematic diagram showing the first semiconductor package in which minute bumps are formed on connection pads from which solder halls have been removed;

FIG. 2A is a schematic diagram showing a configuration of a second semiconductor package used in the method of manufacturing a semiconductor device according to the first embodiment of this invention;

FIG. 2B is a schematic diagram showing the second semiconductor package in which solder balls have been removed;

FIG. 2C is a schematic diagram showing the second semiconductor package in which minute bumps are formed on connection pads from which the solder balls have been removed;

FIG. 3 is an enlarged view of the region bounded by the dashed line in FIG. 1C or FIG. 2C;

FIG. 4 is a schematic diagram showing a configuration of a flexible printed wiring board used in the method of manufacturing a semiconductor device according to the first embodiment of this invention;

FIG. 5A is a diagram illustrating a state in which the first semiconductor package of FIG. 1c is mounted on the flexible printed wiring board of FIG. 4;

FIG. 5B is a diagram showing a state in which the flexible printed wiring board is begun to be folded;

FIG. 5C is a diagram showing a state in which the flexible printed wiring board has been folded completely;

FIG. 6 is a diagram showing a state in which the second semiconductor package of FIG. 2C is mounted on the folded flexible printed wiring board of FIG. 5C;

FIG. 7A is a schematic diagram showing a configuration of a first semiconductor package used in a method of manufacturing a semiconductor device according to a second embodiment of this invention;

FIG. 7B is a schematic diagram showing the first semiconductor package from which solder balls have been removed;

FIG. 8A is a schematic diagram showing a configuration of a second semiconductor package used in the method of manufacturing a semiconductor device according to the second embodiment of this invention;

FIG. 8B is a schematic diagram showing the second semiconductor package from which solder balls have been removed;

FIG. 9 is a schematic diagram showing a configuration of a flexible printed wiring board used in the method of manufacturing a semiconductor device according to the second embodiment of this invention;

FIG. 10A is a diagram showing a state in which the first semiconductor package of FIG. 7B is mounted on the flexible printed wiring board of FIG. 9B;

FIG. 10B is a diagram showing a state in which the flexible printed wiring board is begun to be folded;

FIG. 10C is a diagram showing a state in which the flexible printed wiring board has been folded completely; and

FIG. 11 is a diagram showing a state in which second semiconductor package of FIG. 8b is mounted on the folded flexible printed wiring board of FIG. 10C.

### DESCRIPTION OF EXEMPLARY EMBODIMENTS

Exemplary embodiments of the invention will be described in detail with reference to the drawings.

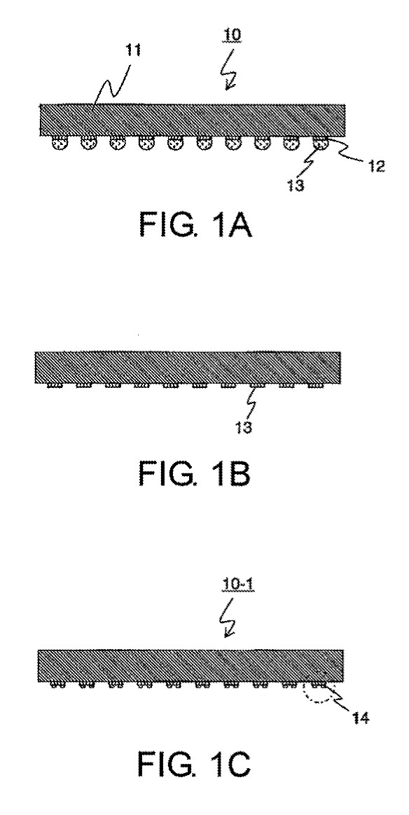

Referring to FIGS. 1 to 6, a method of manufacturing a semiconductor device according to a first embodiment of this invention will be described. The description here will be made on the assumption that a plurality of commercially available BGA (Ball Grid Array) type semiconductor packages are prepared and stacked, using a flexible printed wiring board (FPC) serving as an interposer.

First, a plurality of BGA-type semiconductor packages (two (first and second) semiconductor packages in this example) are prepared. Semiconductor packages called CSP (Chip Size Package) can be used as the BGA-type semiconductor packages.

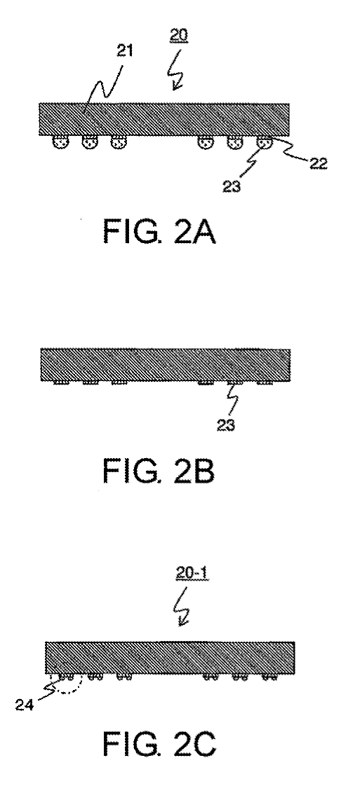

FIG. 1A and FIG. 2A are schematic diagrams showing, respectively, a first and second BGA-type semiconductor package 10, 20. As shown in these figures, the first and second BGA-type semiconductor packages 10, 20 respectively have a package body 11, 21 incorporating a semiconductor chip (not shown), connection pads (third and fourth connection pads) 12, 22 formed one surface of the semiconductor chip, and solder balls 13, 23 formed on the connection pads 12, 22.

As shown in FIG. 1B and FIG. 2B, the solder balls 13, 23 are removed from the semiconductor package 10, 20 to expose the connection pads 12, 22. Then, as shown in FIG. 1c and FIG. 2c, minute bumps (stud bumps) 14, 24 made of gold (Au), for example, are formed on the surface of each of the exposed connection pads 12, 22 by means of a bump bonder to form a first and second semiconductor package 10-1, 20-1, respectively.

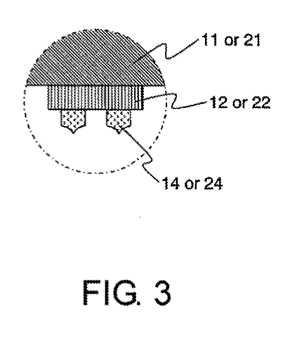

FIG. 3 is an enlarged view of the stud bumps 14, 24 formed on the connection pad 12 or 22. As shown in FIG. 3, each of the connection pads 12, 22 is formed with a plurality of stud bumps 14, 24. This means that each of the stud bumps 14, 24 has such a size that allows formation in plurality on the connection pad 12 or 22. In other words, the area occupied by the stud bump 14, 24 is smaller than the area occupied by the connection pad 12, 22.

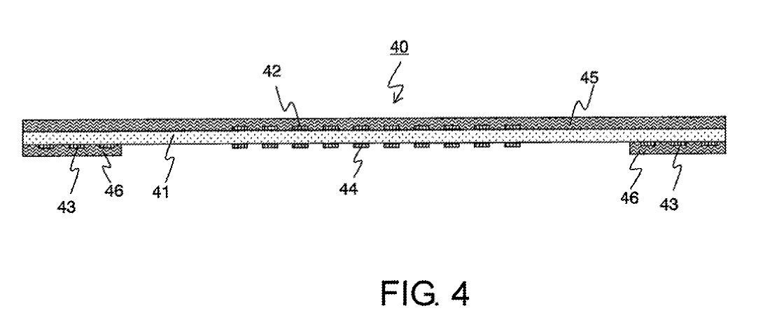

Next, the first semiconductor package 10-1 having the stud bumps 14 formed thereon is mounted on a flexible printed wiring board 40 having a configuration shown in FIG. 4.

The flexible printed wiring board 40 shown in FIG. 4 has a substrate 41 including an insulating layer (not shown) and a wiring layer (not shown), first connection pads 42 formed on the front surface of the substrate 41, second connection pads 43 formed on the back surface of the substrate 41 (in the edge regions on the both sides as viewed in FIG. 4), and connection pads for external connection 44 also formed on the back surface of the substrate 41 (in the central region as viewed in FIG. 4). The first connection pads 42, the second connection pads 43 and the connection pads for external connection 44 are connected to the wiring layer in the substrate 41.

The flexible printed wiring board 40 further has a front-side thermoplastic resin film 45 covering the front surface of the substrate 41 and a back-side thermoplastic resin film 46 covering at least the regions of the back surface where the second connection pads 43 are formed. Herein, the front-side thermoplastic resin film 45 and the back-side thermoplastic resin film 46 are coating films, respectively.

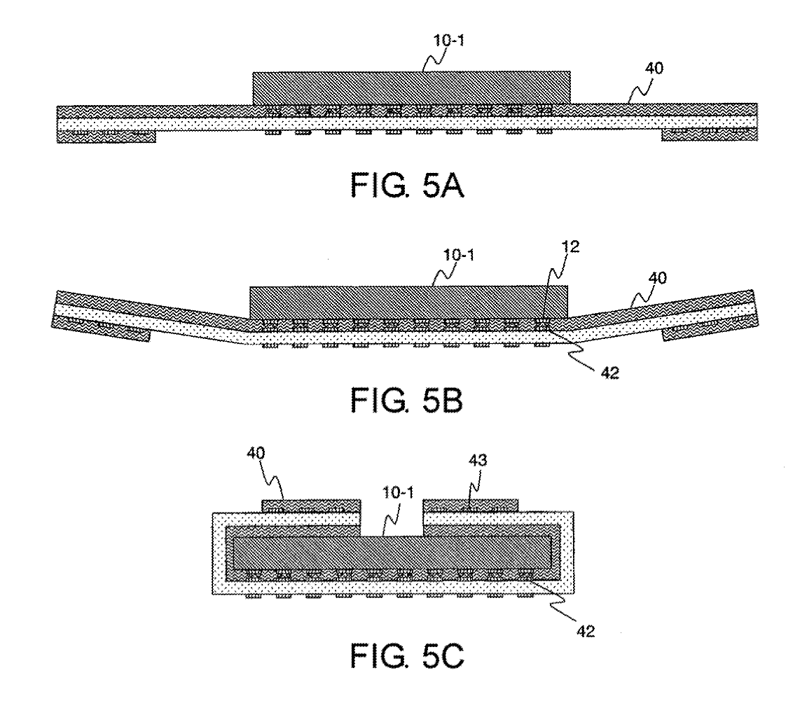

FIG. 5A shows the state in which the first semiconductor package 10-1 is mounted on the flexible printed wiring board 40. When mounting, the first semiconductor package 10-1 is aligned such that each of the connection pads 12 having the stud bumps 14 formed thereon is connected to its corresponding one of the first connection pads 42.

The mounting can be performed by using a semiconductor mounter capable of handling the first semiconductor package 10-1. The semiconductor mounter presses the semiconductor package 10-1 onto the flexible printed wiring board 40 while heating the semiconductor package 10-1, whereby the connection pads 12 on the first semiconductor package 10-1 are connected to the first connection pads 42 on the flexible printed wiring board 40 via the stud bumps 14. In this process, the front-side thermoplastic resin film 45 exhibits adhesion properties due to the heat from the semiconductor package 10-1 and is stuck to the lower surface of the first semiconductor package 10-1. This means that the front-side thermoplastic resin film 45 exhibits adhesion properties by being heated and establishes bond between the first semiconductor package 10-1 and the flexible printed wiring board 40.

The flexible printed wiring board 40 having the first semiconductor package 10-1 mounted thereon is fixed on a heater stage (not shown). The flexible printed wiring board 40 is then folded while being heated. More specifically, as shown in FIGS. 5B and 5C, the flexible printed wiring board 40 is folded along the contour of the first semiconductor package 10-1 such that the semiconductor package 10-1 is surrounded by the flexible printed wiring board 40. In this process as well, the front-side thermoplastic resin film 45 exhibits adhesion properties due to the heat from the heater stage and adheres to the side faces and top face of the first semiconductor package 10-1. As a result, the second connection pads 43 on the flexible printed wiring board 40 are located above the semiconductor package 10-1. Like the first connection pads 42, the second connection pads 43 face upward as viewed in FIG. 5C.

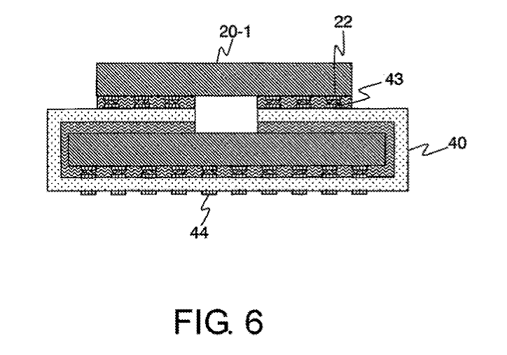

Next, using a semiconductor mounter, the second semiconductor package 20-1 is mounted on the flexible printed wiring board 40 as shown in FIG. 6. In this process, the positional relationship between the second semiconductor package 20-1 and the flexible printed wiring board 40 is adjusted such that each of the connection pads 22 on the second semiconductor package 20-1 is connected to its corresponding one of the second connection pads 43 on the flexible printed wiring board 40. In the same manner as when the first semiconductor package 10-1 is mounted on the flexible printed wiring board 40, the second semiconductor package 20-1 is heated so that the connection pads 22 on the second semiconductor package 20-1 are connected to the second connection pads 43 on the flexible printed wiring board 40 via the stud bumps 24. The second semiconductor package 20-1 and the flexible printed wiring board 40 are connected to each other by means of the back-side thermoplastic resin film 46.

Finally, a solder ball (not shown) is provided by reflow on each of the connection pads for external connection 44 on the flexible printed wiring board 40. The solder ball is used to connect the flexible printed wiring board 40 to another printed wiring board (not shown). In this manner, the semiconductor packages 10-1 and 20-1 are allowed to be connected to an external circuit via the flexible printed wiring board 40.

Thus, a semiconductor device formed by stacking the first semiconductor package 10-1 and the second semiconductor package 20-1 can be obtained.

According to the first embodiment as described above, a semiconductor device (semiconductor module) having a stacked structure (three-dimensional structure) can be manufactured using commercially available semiconductor packages. Moreover, the height in the stacking direction can be reduced by stacking the semiconductor packages 10-1 and 20-1 after removing the solder balls 13 and 23 therefrom. This makes it possible to manufacture a thin semiconductor device (module) without the need of designing special semiconductor packages, resulting in a reduction of costs required for design and development.

Furthermore, according to the first embodiment, the semiconductor packages 10-1 and 20-1 are connected to the flexible printed wiring board 40 by using the stud bumps instead of solder, whereby various problems possibly caused by the use of solder can be avoided. Specifically, the number of times of reflow heating performed on the semiconductor packages can be reduced, and thus the heat stress to the semiconductor device can be reduced, resulting in improved reliability. Furthermore, if solder balls are used to connect the semiconductor packages 10-1 and 20-1 to the flexible printed wiring board 40, various problems may occur when the semiconductor device shown in FIG. 6 is attached to a printed wiring board (not shown), such as solder deformation, solder short circuit, connection failure, and so on. According to this embodiment, however, these problems can be avoided.

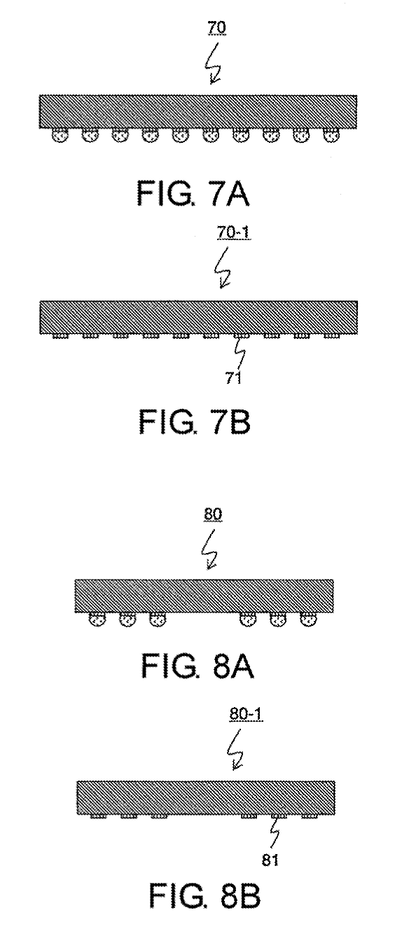

Referring to FIGS. 7 to 11, a method of manufacturing a semiconductor device according to a second embodiment of this invention will be described.

First, first and second semiconductor packages 70 and 80 as shown in FIG. 7A and FIG. 8A are prepared. These semiconductor packages are configured in the same manner as the semiconductor packages shown in FIG. 1A and FIG. 2A. First and second semiconductor packages 70-1 and 80-1 as shown in FIG. 7A and FIG. 8B are obtained by removing solder balls from the semiconductor packages 70 and 80 to expose connection pads 71 and 81.

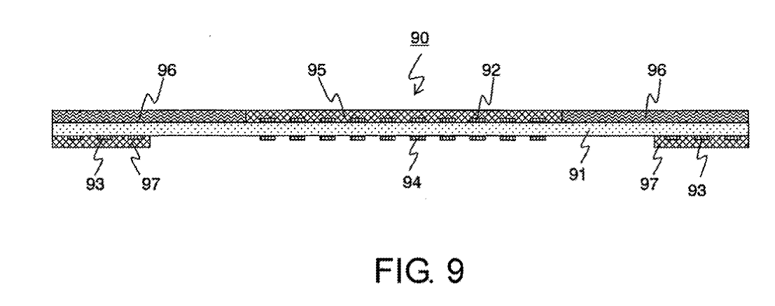

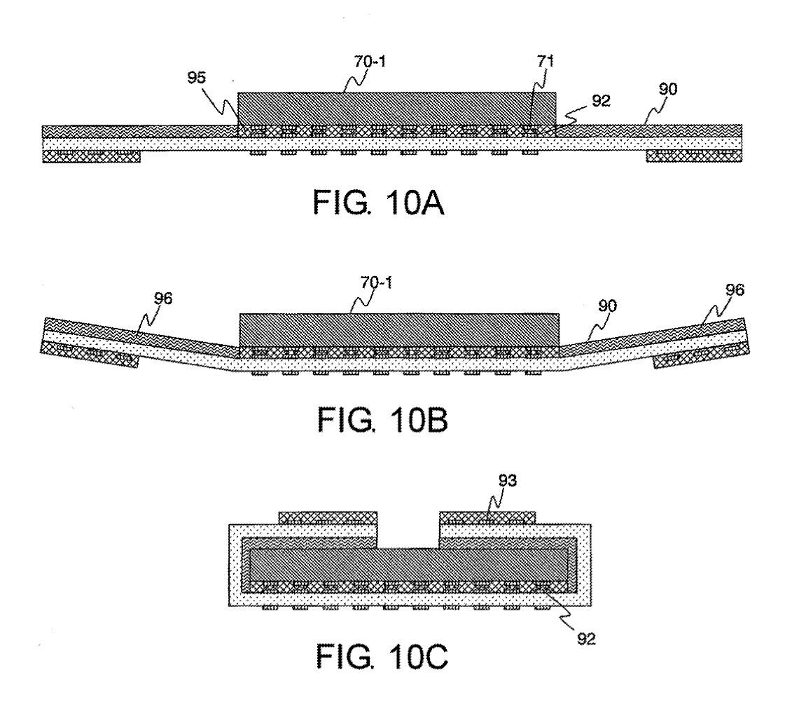

On the other hand, a flexible printed wiring board 90 as shown in FIG. 9 is prepared. This flexible printed wiring board 90 has a substrate 91 including a wiring layer (not shown) and an insulating layer (not shown), first connection pads 92 formed on the front surface of the substrate 91, second connection pads 93 formed on the back surface (in the edge regions on the both sides as viewed in FIG. 9) of the substrate 91, and connection pads for external connection 94 formed also on the back surface (in the central region as viewed in FIG. 9) of the substrate 91. The first connection pads 92, the second connection pads 93 and the connection pads for external connection 94 are connected to the wiring layer in the substrate 41.

The flexible printed wiring board 90 further has a front-side anisotropic conductive film (ACF) 95 covering the region on the front surface thereof where the first connection pads 92 are formed, a thermoplastic resin film 96 covering the other regions on the front surface, and a back-side anisotropic conductive film 97 covering the regions on the back surface where the second connection pad 43 are formed. Herein, the front-side anisotropic conductive film (ACF) 95 and the back-side anisotropic conductive film 97 are coating films, respectively.

Next, as shown in FIG. 10a, the first semiconductor package 70-1 of FIG. 7B is mounted on the surface of the flexible printed wiring board 90 of FIG. 9 using a semiconductor mounter. Specifically, the first semiconductor package 70-1 is aligned such that each of the connection pads 71 on the first semiconductor package 70-1 faces its corresponding one of the first connection pads 92 on the flexible printed wiring board 90. The first semiconductor package 70-1 is then pressed to the flexible printed wiring board 90 while being heated. The anisotropic conductive film 95 is made of a thermosetting resin in which fine conductor particles are dispersed, and exhibits electrical conductivity when the conductor particles are mutually connected by heat and pressure. This means that, when the semiconductor package 70-1 is pressed to the flexible printed wiring board 90 while being heated (i.e. thermally compressed to the flexible printed wiring board 90), electrical connection is established between the connection pads 71 on the first semiconductor package 70-1 and the first connection pads 92 on the flexible printed wiring board 90.

Next, as shown in FIGS. 10B and 10C, the flexible printed wiring board 90 is placed on a heater stage (not shown) and folded while being heated thereby, so that the first semiconductor package 70-1 is surrounded by the flexible printed wiring board 90. In this process, the thermoplastic resin film 96 exhibits adhesion properties due to the heat from the heater stage and is stuck on the side faces and top face of the first semiconductor package 70-1. As a result, the second connection pads 93 on the flexible printed wiring board 90 are located above the semiconductor package 70-1, facing upwards.

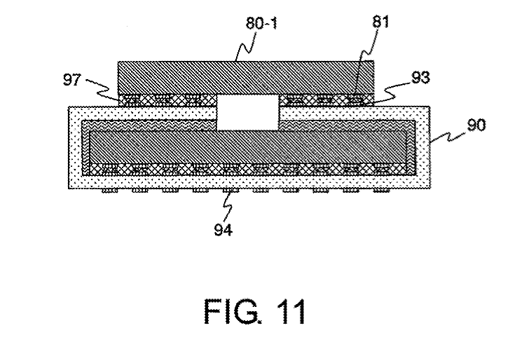

The second semiconductor package 80-1 is then mounted on the flexible printed wiring board 90 as shown in FIG. 11 with the use of a semiconductor mounter. In this process, the positional relationship between the second semiconductor package 80-1 and the flexible printed wiring board 90 is adjusted such that each of the connection pads 81 on the second semiconductor package 80-1 is connected to its corresponding one of the second connection pads 93 on the flexible printed wiring board 90, and the second semiconductor package 80-1 is pressed onto the flexible printed wiring board 90 while being heated. Electrical connection is thereby established between the connection pads 81 on the second semiconductor package 80-1 and the second connection pads 93 on the flexible printed wiring board 90 by means of conductor particles in the anisotropic conductive resin film 97.

Finally, a solder ball is provided by reflow on each of the connection pads for external connection 94 on the flexible printed wiring board 90, and the manufacture of a semiconductor device is completed.

According to this second embodiment as well, a semiconductor device having a stacked structure (three-dimensional structure) can be manufactured using commercially available semiconductor packages. Moreover, the height in the stacking direction can be reduced by stacking the semiconductor packages 10-1 and 20-1 after removing the solder balls 13 and 23 therefrom. Like the first embodiment, various problems can be avoided which may occur when the semiconductor packages are connected to a printed wiring board using the solder balls.

According to embodiments of this invention, it is made possible to stack a semiconductor package on another one by mounting the semiconductor package on a flexible printed wiring board provided with a thermoplastic resin film or an anisotropic conductive film thereon.

Although this invention has been described in conjunction with a few preferred exemplary embodiments thereof, this invention is not limited to the foregoing embodiments but may be modified in various other manners within the scope of the appended claims. For example, the foregoing embodiments have been described on the case in which two different types of semiconductor packages are stacked, it is also possible to stack semiconductor packages of the same type (of the same shape). Three or more semiconductor packages either of different types or of the same type can be stacked as well. In addition, although the foregoing embodiments have been described on the case of using BGA-type semiconductor packages, other types, for example LGA-type semiconductor packages may be stacked.

The whole or part of the exemplary embodiments disclosed above can be described as, but not limited to, the following supplementary notes.

(Supplementary Note 1) A method of manufacturing a semiconductor device comprising the steps of preparing a flexible printed wiring board having a first connection pad formed on the front surface thereof, a second connection pad formed on the back surface thereof, and a thermoplastic resin film or anisotropic conductive film covering the regions of the flexible printed wiring board where the first and second connection pads are formed, and a semiconductor package having a third connection pad formed on the back surface thereof; mounting the semiconductor package on the front surface of the flexible printed wiring board such that the third connection pad is connected to the first connection pad; and folding the flexible printed wiring board while heating the same such that the second connection pad is located above the front surface of semiconductor package, facing in the same direction as the front surface of the semiconductor package.

(Supplementary Note 2) The method of manufacturing a semiconductor device as described in Supplementary Note 1, comprising the step of removing a solder ball formed on the third connection pad before mounting the semiconductor package on the flexible printed wiring board.

(Supplementary Note 3) The method of manufacturing a semiconductor device as described in Supplementary Note 1 or 2, wherein the regions where the first connection pad and the second connection pad are formed are covered with the thermoplastic resin film, and the method further comprises the step of forming a bump occupying a smaller area than the third connection pad on the third connection pad before mounting the semiconductor package on the flexible printed wiring board.

(Supplementary Note 4) The method of manufacturing a semiconductor device as described in Supplementary Note 1 or 2, wherein the regions where the first connection pad and the second connection pad are formed are covered with the anisotropic conductive film, and the method further comprises the step of thermally compressing the third connection pad to the first connection pad.

(Supplementary Note 5) The method of manufacturing a semiconductor device as described in any one of Supplementary Notes 1 to 4, further comprising the steps of: preparing another semiconductor package having a fourth connection pad formed on the back surface thereof; folding the flexible printed wiring board; and mounting the another semiconductor package on the back surface of the flexible printed wiring board such that the fourth connection pad is connected to the second connection pad.

(Supplementary Note 6) The method of manufacturing a semiconductor device as described in Supplementary Note 5, comprising the step of removing a solder ball formed on the fourth connection pad before mounting the another semiconductor package on the flexible printed wiring board.

(Supplementary Note 7) The method of manufacturing a semiconductor device as described in Supplementary Note 5 or 6, comprising the step of forming a bump occupying a smaller area than the fourth connection pad on the fourth connection pad before mounting the another semiconductor package on the flexible printed wiring board.

(Supplementary Note 8) The method of manufacturing a semiconductor device as described in Supplementary Note 5 or 6, comprising the step of thermally compressing the fourth connection pad to the second connection pad.

(Supplementary Note 9) A semiconductor device manufactured by the method of manufacturing a semiconductor device as described in any one of Supplementary Notes 1 to 8.

What is claimed is:

1. A method of manufacturing a semiconductor device, comprising:
preparing a flexible printed wiring board having a first connection pad formed on a front surface, a second connection pad formed on a back surface, and a coating film covering regions of the flexible printed wiring board where the first and second connection pads are formed, and a semiconductor package having a third connection pad formed on a back surface;
mounting the semiconductor package on the front surface of the flexible printed wiring board so that the third connection pad is connected to the first connection pad; and
folding the flexible printed wiring board so that the second connection pad is located above the front surface of the semiconductor package to face in the same direction as a front surface of the semiconductor package.

2. The method of manufacturing a semiconductor device as claimed in claim 1, further comprising:
removing a solder ball formed on the third connection pad before mounting the semiconductor package on the flexible printed wiring board.

3. The method of manufacturing a semiconductor device as claimed in claim 1, wherein the coating film is a thermoplastic resin film, and the method further comprises forming a bump occupying a smaller area than the third connection pad on the third connection pad before mounting the semiconductor package on the flexible printed wiring board.

4. The method of manufacturing a semiconductor device as claimed in claim 1, wherein the coating film is a thermoplastic resin film is an anisotropic conductive film, and the method further comprises thermally compressing the third connection pad to the first connection pad.

5. The method of manufacturing a semiconductor device as claimed in claim 1, further comprising:
preparing another semiconductor package having a fourth connection pad formed on a back surface; and
mounting the another semiconductor package on the back surface of the flexible printed wiring board so that the fourth connection pad is connected to the second connection pad after folding the flexible printed wiring board.

6. The method of manufacturing a semiconductor device as claimed in claim 5, further comprising:
removing a solder ball formed on the fourth connection pad before mounting the another semiconductor package on the flexible printed wiring board.

7. The method of manufacturing a semiconductor device as claimed in claim 5, further comprising:
forming a bump occupying a smaller area than the fourth connection pad on the fourth connection pad before mounting the another semiconductor package on the flexible printed wiring board.

8. The method of manufacturing a semiconductor device as claimed in claim 5, further comprising:
thermally compressing the fourth connection pad to the second connection pad.

9. The method of manufacturing a semiconductor device as claimed in claim 1, wherein the folding of the flexible printed wiring board is carried out while heating.
